(19) United States
(12) Patent Application Publication
(10) Pub. No.: US 2005/0148191 A1
(43) Pub. Date: Jul. 7, 2005

(54) Method of manufacturing semiconductor device

(76) Inventors: Norimitsu Shimizu, Miyazaki (JP); Osamu Koike, Miyagi (JP)

Correspondence Address: RABIN & BERDO, P.C.;Suite 500, 1101 14th Street, Washington, DC, 20005, US

(21) Appl. No.: 10/866,032

(22) Filed: Jun. 14, 2004

(30) Foreign Application Priority Data
Jan. 7, 2004 (JP) 002407/2004

(51) Int. Cl. H01L 21/311

(52) U.S. Cl. 438/700

(57) ABSTRACT

A laminated film of a pad oxide film (12) and a silicon nitride film (13) is deposited on a silicon substrate (11). Further, a polysilicon film (14) is formed on the laminated film. The silicon film (14), the silicon nitride film (13) and the pad oxide film (12) are sequentially etched through the use of a resist mask (15). Then the silicon substrate (11) is etched with the polysilicon film (14) as a mask to form a trench (16).

### BACKGROUND OF THE INVENTION

1. Field of the Invention

The present invention relates to a method-of manufacturing a semiconductor device, and particularly to a method of forming a trench corresponding to a device isolation region formed in a semiconductor substrate.

2. Description of the Related Art

Higher levels of integration have been advanced in an LSI device. A further micro-fabrication technique has been required to realize it. The recent LSI device manufacturing technology is moving toward adopting a shallow trench isolation (STI) structure capable of bringing a device isolation region into fine or micro form and forming it with satisfactory accuracy in place of the conventional LOCOS isolation structure as a device isolation technique.

A method of forming a conventional STI structure will first be explained in brief with reference to FIGS. 1 and 2. A pad oxide film 2 is formed on a silicon substrate 1 by a thermal oxidation method. Further, a silicon nitride film 3 is deposited on the pad oxide film 2 by a CVD method. Next, a resist pattern 4 is formed (see FIG. 1) and the silicon nitride film 3, pad oxide film 2 and silicon substrate 1 are sequentially etched with the resist pattern 4 as a mask to remove the resist 4. By doing so, a trench 5 used as a device isolation trench or groove is formed (see FIG. 2).

Although not shown in the drawings, the silicon nitride film 3 and the pad oxide film 2 are sequentially removed by the normal method. A silicon oxide film is formed by the CVD method so as to be perfectly embedded into the trench 5 over the whole surface. If the silicon oxide film is planarized by a CMP method and then embedded into only the trench 5, then an STI structure is formed.

Since the STI structure has a device isolation region, it is important to control the depth of the trench in order to perfectly isolate between elemental devices. The conventional trench forming method has put emphasis on the fact that in order to ensure a target trench depth, an etching rate is particularly controlled to uniformize etching characteristics.

In the conventional forming method, however, the difference in type between respective films to be subjected to etching and a variation in etching rate due to the difference in model between etching apparatuses were obliged to take into consideration in order to batch-etch a silicon oxide film, a silicon nitride film and a silicon substrate through a resist mask. Further, in order to ensure a target trench depth, there was a need to confirm the state of each etching apparatus each time the film to be etched changes.

A problem arises in that an etching reactive product containing carbon generated from the resist is formed because etching is done with the resist as the mask, and the reactive product is deposited on the silicon substrate, thereby interfering with the etching of the silicon substrate.

### SUMMARY OF THE INVENTION

The present invention has been made to solve the foregoing problem. Therefore, the present invention aims to etch a silicon substrate using a polysilicon mask without etching the silicon substrate using a resist mask to thereby form a trench.

That is, an insulating film that does not belong to a silicon system, e.g., a laminated film of a silicon oxide film and a silicon nitride film corresponding to an upper layer is formed on a silicon substrate. A polysilicon film is formed on the laminated film. Thereafter, the polysilicon film is patterned by a resist. Then the resist is removed and the silicon substrate is etched with the polysilicon film as a mask. The end point of etching can be detected from exposure of the silicon nitride film.

Since the silicon substrate is etched without using the resist mask in the present invention, the carbon-containing reactive product is not deposited over the silicon substrate, and the etching rate of the silicon substrate can be maintained uniformly. Since the etching rates of the polysilicon film and the silicon substrate can be controlled substantially equally, the depth of the trench is accurately controlled owing to the coincidence of both the depth of the trench and the thickness of the polysilicon film.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a process sectional view showing a method of forming a trench, according to a prior art;

FIG. 2 is a process sectional view following FIG. 1, illustrating the trench forming method according to the prior art;

FIG. 3 is a process sectional view showing a method of forming a trench, according to an embodiment of the present invention;

FIG. 4 is a process sectional view following FIG. 3, illustrating the trench forming method according to the embodiment of the present invention; and

FIG. 5 is a process sectional view following FIG. 4, showing the trench forming method according to the embodiment of the present invention.

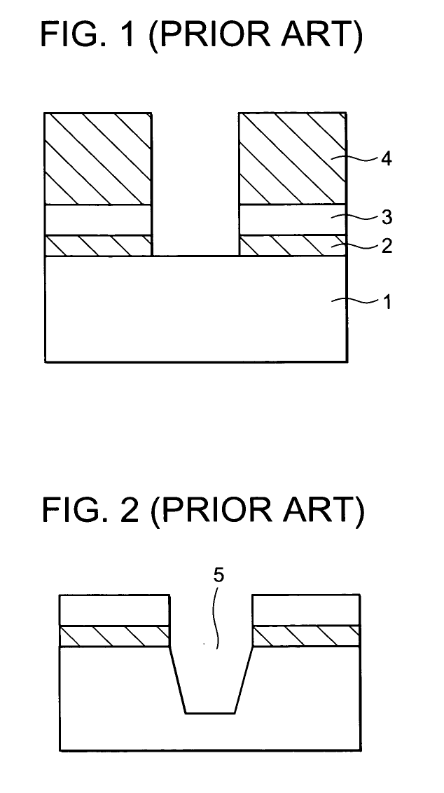

### DETAILED DESCRIPTION OF THE INVENTION

A preferred embodiment of the present invention will hereinafter be described with reference to the accompanying drawings.

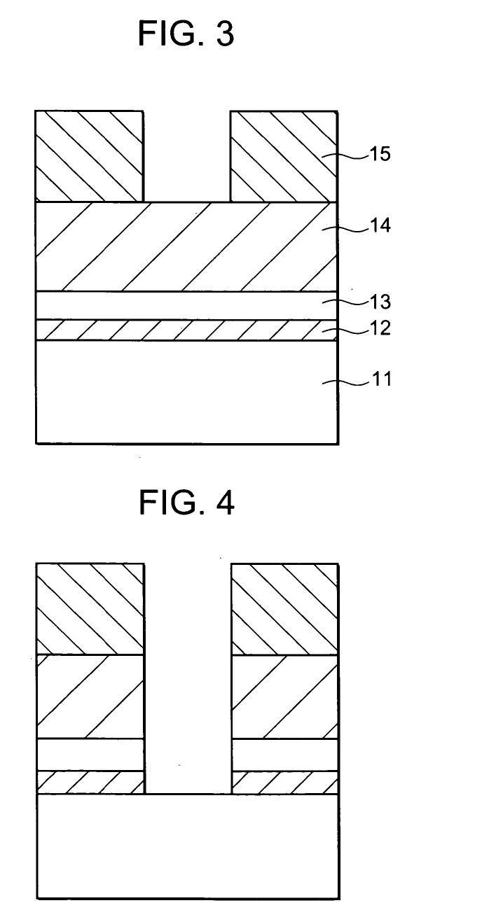

FIGS. 3 through 6 are respectively views showing a method of manufacturing a semiconductor device, according to an embodiment of the present invention. The present embodiment will explain, as an example, a case in which the depth of a trench is 250 nm.

A pad oxide film 12 is first formed on a silicon substrate 11 by a thermal oxidation method, and a silicon nitride film 13 is formed thereon with a thickness of 150 nm by a CVD method. Subsequently, a polysilicon film 14 is deposited on the silicon nitride film 13 with a thickness of 250 nm. Next, a resist pattern 15 is formed on the polysilicon film 14 by photolithography technology (see FIG. 3).

Then the polysilicon film 14 is etched with the resist pattern 15 as a mask. The etching is carried out using, for example, an ICP type dry etching system under the condition of a pressure of 1.3 Pa, an RF power=400 W, a gas of Cl₂/HBr/O₂ and a flow rate=50/150/10 sccm.

Further, the pad oxide film 12 and the silicon nitride film 13 are etched with the resist pattern 15 as the mask (see FIG. 4). The etching conditions are given as a pressure of 8.0 Pa, an RF power=400 W, a gas of CHF₃/Ar/O₂ and a flow rate=15/75/3 sccm through the use of the ICP type dry etching system, for example.

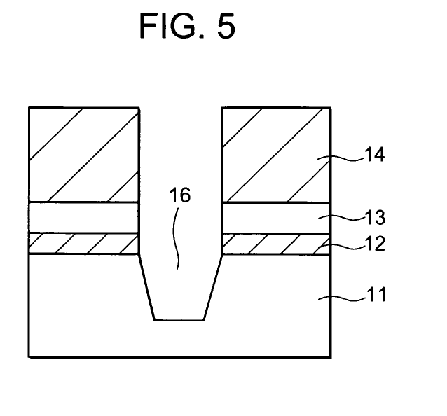

Then the resist 15 is subjected to ashing removal and thereafter the silicon substrate 11 is etched with the polysilicon film 14 as a mask, so that a trench 16 can be formed (see FIG. 5). The etching conditions are given as a pressure of 1.3 Pa, an RF power=400 W, a gas of Cl₂/HBr/O₂ and a flow rate=50/150/10 sccm under the use of the ICP type dry etching system.

Since the present etching is based on the condition that the polysilicon film 14 is etched at substantially the same etching rate as the silicon substrate 11, the trench 16 having the same depth as the thickness of the polysilicon film 14 can be formed if the complete removal of the polysilicon film 14 is end-point detected.

Although the present embodiment has explained the laminated film corresponding to a layer below the polysilicon as a two-layer film, a multilayer film of greater than the two layers, which comprises silicon oxide film/silicon nitride film/silicon oxide film or the like, may be adopted. Further, the mask film may be an amorphous silicon film if it is of a silicon system. The setting of the types of these films and the like can be determined in matching with other process conditions, particularly, etching conditions.

According to the present invention as described above, trench etching is enabled without depositing any reactive product on a silicon substrate. Further, since etching is carried out under the condition that a mask film and a silicon substrate are equal to each other in etching rate, a trench having an accurate depth can be formed.

While the present invention has been described with reference to the illustrative embodiment, this description is not intended to be construed in a limiting sense. Various modifications of the illustrative embodiment, as well as other embodiments of the invention, will be apparent to those skilled in the art on reference to this description. It is therefore contemplated that the appended claims will cover any such modifications or embodiments as fall within the true scope of the invention.

1. A method of manufacturing a semiconductor device, comprising the steps of:
forming an insulating film on a silicon substrate and forming a silicon film on the insulating film;
etching the silicon film and the insulating film with a resist as a mask; and
removing the resist and thereafter etching the silicon substrate with the silicon film as a mask to thereby form a trench.

2. A method according to claim 1, wherein the silicon film is a film selected from either polycrystal silicon or amorphous silicon.

3. A method according to claim 2, wherein the depth of the trench is equal to the thickness of the silicon film.

4. A method according to claim 2, wherein the insulating film is a multilayer film of a silicon oxide film and a silicon nitride film.

5. A method according to claim 4, wherein the multilayer film is a two-layer film comprising a lower film corresponding to the silicon oxide film and an upper film corresponding to the silicon nitride film.

6. A method according to claim 2, wherein the etching end point of the trench is carried out by detecting exposure of the surface of the insulating film.
